(19) United States
(12) Patent Application Publication
(10) Pub. No.: US 2020/0326571 A1
(43) Pub. Date: Oct. 15, 2020

(54) DISPLAY DEVICE

(71) Applicant: Japan Display Inc., Tokyo (JP)

(72) Inventors: Akihiro HANADA, Tokyo (JP); Tomoyuki ITO, Tokyo (JP)

(21) Appl. No.: 16/911,930

(22) Filed: Jun. 25, 2020

Related U.S. Application Data
(63) Continuation of application No. PCT/JP2018/044508, filed on Dec. 4, 2018.

(30) Foreign Application Priority Data
Jan. 15, 2018 (JP) 2018-003913

(51) Int. Cl. G02F 1/1368; H01L 29/786; H01L 27/12; H01L 27/32

(52) U.S. Cl. CPC G02F 1/1368; H01L 29/78675; H01L 27/1222; H01L 27/3244; H01L 27/1251

(57) ABSTRACT

The purpose of the present invention is to suppress the change in characteristics of the TFT formed on the polyimide substrate. An example of the present invention is a display device having a first TFT of an oxide semiconductor film and a second TFT of a polysilicon film formed on the substrate made of resin including the first TFT and the second TFT do not overlap in a plan view, a distance between the second TFT and the substrate is shorter than a distance between the first TFT and the substrate in a cross sectional view, a second polysilicon film is formed between the oxide semiconductor film and the substrate, the second polysilicon film is made of the same material as the first polysilicon film and is formed on the same layer that the first polysilicon is formed.

The present application is a continuation application of International Application No. PCT/JP2018/044508, filed on Dec. 4, 2018, which claims priority to Japanese Patent Application No. 2018-003913, filed on Jan. 15, 2018. The contents of these applications are incorporated herein by reference in their entirety.

### BACKGROUND OF THE INVENTION

### (1) Field of the Invention

The present invention relates to the display devices, specifically the flexible display devices that the substrates can be curved.

### (2) Description of the Related Art

The organic EL display device and the liquid crystal display device can be used in curved state by making those devices thin. In those cases, the substrate, on which elements are formed, is made of thin glass or thin resin.

In the organic EL display device, the organic light emitting layer is driven by a driving transistor made of TFT (Thin Film Transistor). When noise intrudes into the driving transistor, the threshold voltage of the driving transistor changes, thus, accurate reproducing of brightness becomes impossible.

Patent document 1 discloses the organic EL display device, which includes a driving transistor formed by a top gate type TFT, has a metal thin film for shield on a layer under the TFT in order to suppress a change of the threshold voltage of the TFT caused by external noise.

### PRIOR ART DOCUMENTS

Patent document 1:

Japanese Translation of PCT International Application Publication No. 2017-505457

### SUMMARY OF THE INVENTION

The flexible organic EL display device can be realized when the substrate is formed by resin as polyimide. The inventor, however, found that a change of brightness in screen occurs after a long operation time in the organic EL display device having a resin substrate compared with in the organic EL display device having a glass substrate. This change in screen brightness is supposed to be caused by that the charge distribution changes in the resin substrate after long operation, consequently, the charge up near the driving transistor influences the characteristics of the driving TFT.

The TFT formed by the oxide semiconductor has a characteristic that a leak current is low. Therefore, it enables a low frequency driving for the organic EL display device and thus, enables a low power consumption for operating the organic EL display device. The TFT formed by the oxide semiconductor, however, has a problem that it is easily influenced by charge up in the substrate and so forth.

Further, if the TFT formed by the oxide semiconductor is used in the liquid crystal display device, the TFT is influenced by back light. Therefore, in that case, a light shielding film is necessary.

The TFT formed by the Low Temperature Poly-Silicon (herein after LTPS (Low Temperature Poly-Silicon)) has high mobility of carriers, however, it has rather higher leak current. Therefore, it is reasonable to use the TFT formed by the LTPS in the peripheral driving circuit such as a scan line driving circuit, and to use the TFT formed by the oxide semiconductor for the switching transistor or the driving transistor in the pixel. Such a structure is called a hybrid structure. In this specification, the polysilicon means the low temperature poly-silicon; however, the present invention is applicable even when the polysilicon is formed by other method.

In the hybrid structure, the TFT formed by the LIPS and the TFT formed by the oxide semiconductor are formed in a continuous process. In this case, a mitigation of influence by charge up, light shading against the back light and so forth need to be considered for both kinds of the TFTs.

The purpose of the present invention is to realize the structure that can suppress the influence of charge up in the substrate, suppress the influence of external light to the TFT when the resin substrate is used; in addition, to realize the hybrid structure that can reasonably solve those problems.

The present invention solves the above explained problems; the concrete measures are as follows.

(1) A display device having a first TFT of an oxide semiconductor film and a second TFT of a polysilicon film formed on the substrate made of resin comprising:

the first TFT and the second TFT do not overlap in a plan view,

a distance between the second TFT and the substrate is shorter than a distance between the first TFT and the substrate in a cross sectional view,

a second polysilicon film is formed between the oxide semiconductor film and the substrate,

the second polysilicon film is made of the same material as the first polysilicon film and is formed on the same layer that the first polysilicon is formed.

(2) A display device having a first TFT of an oxide semiconductor film formed on the substrate made of resin comprising:

a first conductive film is formed on the substrate overlapping with the oxide semiconductor film, in a plan view,

an undercoat film made of an inorganic film is formed on the first conductive film,

the oxide semiconductor film has a channel length and a channel width,

wherein, in the channel length direction, a length of the first conductive film is longer than a length of the oxide semiconductor film.

(3) The display device according to (2),

wherein a second TFT of a polysilicon film is formed on the substrate, the first TFT and the second TFT do not overlap in a plan view, and

a distance between the second TFT and the substrate is shorter than a distance between the first TFT and the substrate, in a cross sectional view.

### BRIEF DESCRIPTION OF THE DRAWINGS

FIG. 1 is a plan view of the organic EL display device;

FIG. 2 is a cross sectional view of the display area of the organic EL display device;

FIG. 3 is an equivalent circuit of the pixel of the organic EL display device;

FIG. 4 is a cross sectional view to explain the charge up in the substrate;

FIG. 5 is a cross sectional view to explain the influence of the charge up in the substrate;

FIG. 6 is a cross sectional view of the TFT and its vicinity according to a comparative example;

FIG. 7 is a cross sectional view of the TFT and its vicinity according to the present invention;

FIG. 8 is a cross sectional view that shows a part of the of the manufacturing process according to the present invention;

FIG. 9 is a plan view of the TFT and its vicinity according to the present invention;

FIG. 10 is a cross sectional view of the TFT and its vicinity according to embodiment 2;

FIG. 11 is a cross sectional view of the TFT and its vicinity according to a second example of embodiment 2;

FIG. 12 is a cross sectional view of the TFT and its vicinity according to a third example of embodiment 2;

FIG. 13 is a cross sectional view of the TFT and its vicinity according to a fourth example of embodiment 2;

FIG. 14 is a plan view of the liquid crystal display device;

FIG. 15 is a cross sectional view of the display area of the liquid crystal display device;

FIG. 16 is an example of the voltage that is applied to the scan line.

### DETAILED DESCRIPTION OF THE PREFERRED EMBODIMENTS

The present invention will be explained in detail referring to the following embodiments.

### Embodiment 1

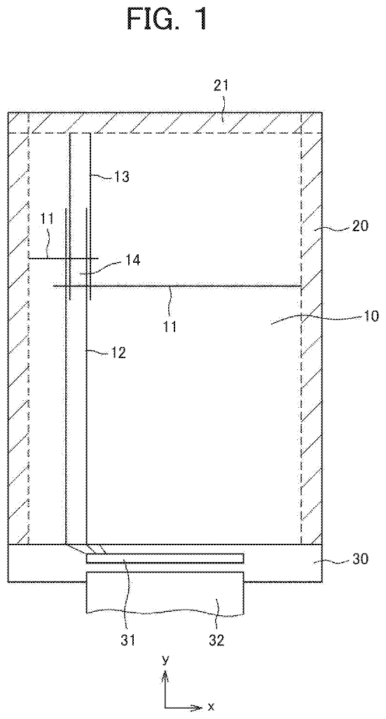

FIG. 1 is a plan view of the organic EL display device having the flexible substrate 100, which the present invention is applied. The organic EL display device in FIG. 1 has the display area 10 and the terminal area 30. In the display area 10, the scan lines 11 extend in the lateral direction (x direction) and are arranged in the longitudinal direction (y direction). The video signal lines 12 and the power lines 13 extend in the longitudinal direction and are arranged in the lateral direction. The pixel 14 is formed in the area surrounded by the scan lines 11 and the video signal lines 12 or the power lines 33.

In FIG. 1, the terminal area 30 is formed in the area where the display area 10 is not formed; the driver IC 31 is installed in the terminal area 30. The video signals are arranged in the driver IC 31 and supplied to the display area 10. Further, the flexible wiring substrate 32 is connected to the terminal area 30 to supply powers and signals to the organic EL display device.

In FIG. 1, the scan line driving circuits 20 are formed at both sides of the display area 10. The current supply region 21 is formed at the top side (upper side in y direction) of the display area 10. The current is supplied to the current bus line from the flexible wiring substrate 31, which connects to the terminal area 30; the current bus line is wired to the current supply region 21, which is located at the top side (upper side in y direction) of the display area 10. Then the current is supplied to the pixels 14 from the current supply region 21 by the power lines 13. This structure is to avoid a concentration of wirings at the bottom side of the display area 10.

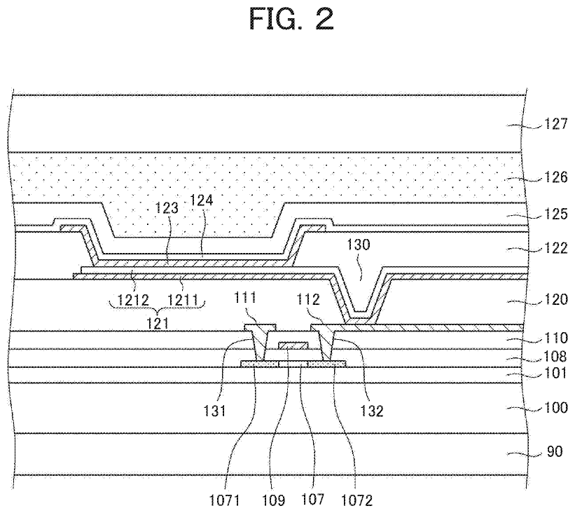

FIG. 2 is a cross sectional view that shows the layer structure in the display area 10 of the organic EL display device shown in FIG. 1. In FIG. 2, the glass substrate 90 is removed after the flexible display device is completed; however, sometimes, the glass substrate 90 may occasionally remain as the supporting substrate for the completed flexible display device. Namely, the sole resin substrate cannot pass the manufacturing process, therefore, elements for the organic EL display device are formed on the glass substrate 90; after the organic EL display device is completed, the glass substrate 90 is removed from the organic EL display device by laser abrasion, etc.

In FIG. 2, the TFT substrate 100 made of resin is formed on the glass substrate 90. The polyimide is used as the resin. The polyimide has superior characteristics as a substrate of the flexible display device because of its mechanical strength, its heat resistance and so forth. Herein after, the resin substrate means the polyimide substrate.

The material, which includes polyamic acid, for the polyimide is coated by slit coater, rod coater, or inkjet and so forth on the glass substrate 90; then, it is baked to be imidized and solidified. A thickness of the polyimide substrate 100 is 10 to 20 microns. The polyimide is, however, easily charge up compared with the glass. The reason is supposed to be as that the polyimide is not a complete insulating material compared with the glass, thus, charges can move in the polyimide influenced by potential of the electrodes, which are formed on the substrate.

In FIG. 2, the undercoat film 101 is formed on the TFT substrate 100 to prevent the semiconductor film 107 and the organic EL layer 123 from being contaminated by moisture or impurities in the polyimide substrate 100. The undercoat film 101 is e.g. formed by a three-layer laminated film, which the silicon nitride (SiN) film is sandwiched by the silicon oxide (SiO) films. In addition, sometimes, the aluminum oxide (AlOx) film is added.

The semiconductor film 107 is formed on the undercoat film 101. The semiconductor film 107 is e.g. made of the oxide semiconductor film. The oxide semiconductor film 107 can be formed at the temperature of 350 centigrade, which the polyimide can endure. Among the oxide semiconductors, optically transparent and amorphous materials are called TAOS (Transparent Amorphous Oxide Semiconductor). Examples of TAOS are indium gallium zinc oxide (IGZO), indium tin zinc oxide (ITZO), zinc oxide nitride (ZnON), and indium gallium oxide (IGO) and so forth. In this invention, it is explained that the IGZO is used for the oxide semiconductor film 107

The gate insulating film 108 is formed on the semiconductor film 107; the gate electrode 109 is formed on the gate insulating film 108. The gate electrode 109 is made of e.g. MoW and so forth, however, if a low resistance is necessary, a laminated film as that the Al film is sandwiched by the Titanium films etc. After that, the ion implantation such as Ar implantation is performed, using the gate electrode as the mask, to form drain 1071 and the source 1072 in the oxide semiconductor film 107. The channel is formed in the semiconductor film 107 just beneath the gate electrode 109.

The interlayer insulating film 110 is formed covering the gate electrode 109. The drain electrode 111 and the source electrode 112 are formed on the interlayer insulating film 110. The through holes 131 and 132 are formed in the interlayer insulating film 110 and the gate insulating film 108; the drain electrode 111 and the drain 1071 are connected via the through hole 131, and the source electrode 112 and the source 1072 are connected via the through hole 132.

The organic passivation film 120 is formed covering the drain electrode 111, the source electrode 112, and the interlayer insulating film 110. The organic passivation film 120 is made of transparent resin as acrylic resin. The organic passivation film 120 has also a role as a flattening film, therefore, it is made thick as 2 to 4 microns.

A laminated film of the reflection film 1211 and the anode 1212 is formed on the organic passivation film 120. The laminated film of the reflection film 1211 and the anode 1212 is called the lower electrode 121. The reflection film 1211 is made of silver, which has a high reflectance, and the anode 1212 is made of ITO (Indium Tin Oxide). The through hole 130 is formed in the organic passivation film 120 to connect the source electrode 112 and the lower electrode 121.

The bank 122 is formed covering the lower electrode 121. The bank 122 is made of transparent resin as acrylic resin. The role of the bank 122 is to form a step coverage to prevent a breaking of the organic EL layer 123 at the edge of the lower electrode 121 as well as to partition the pixels 14.

The organic EL layer 123 is formed in the hole formed in the bank 122. The organic EL layer 123 is a laminated film comprising e.g., from lower side, the hole injection layer, the hole transport layer, the light emitting layer, the electron transport layer, the electron injection layer, and so forth. A thickness of each layers is very thin as several nm to 100 nm.

The upper electrode 124, which is a cathode, is formed covering the organic EL layer 123. The cathode 124 is formed on all over the display area 10 in common to pixels. The cathode 124 is made of the transparent conductive film of e.g. ITO, IZO (Indium Zinc Oxide), AZO (Antimony Zinc Oxide) and so forth or a thin film of metal as silver, etc.

After that, the protective film 125 is formed covering the cathode 124 to prevent intrusion of moisture from the side of the cathode 124. The protective film 125 is made of SiN formed by CVD. The protective film 125 is formed by low temperature CVD as 100 centigrade since the organic EL layer 123 is weak against heat. The protective film 125 may be a laminated film including the transparent resin film made of e.g. acrylic resin for mechanical protection.

Since the organic EL display device of top emission type has reflection electrodes 1211, the external light is reflected from the screen. Therefore, the organic EL display device has the polarizing plate 127 adhered to the display surface to prevent the reflection of the external light. The polarizing plate 127 has the adhesive 126, which is pressure bonded to the organic EL display device. A thickness of the adhesive 126 is e.g. 30 microns and a thickness of the polarizing plate 127 is e.g. 100 microns.

As described above, the flexible display device is formed on the glass substrate 90; subsequently, the laser beam is irradiated at the interface between the TFT substrate 100 and the glass substrate 90 to remove the glass substrate 90 form the TFT substrate 100. As a result, the flexible display device having a resin substrate is completed.

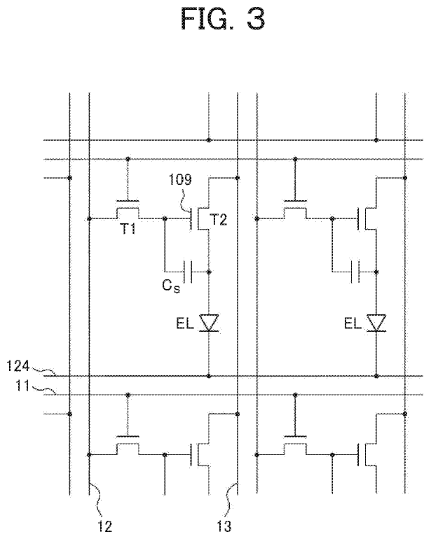

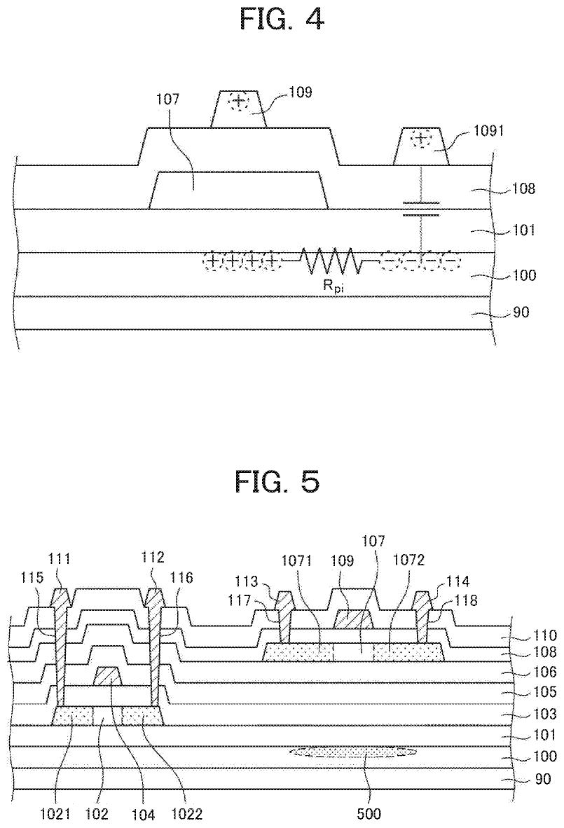

FIGS. 3 and 4 explain mechanism why the source current changes in the driving TFT taking an example in the organic EL display device. FIG. 3 is an equivalent circuit in the pixel of the organic EL display device. In FIG. 3, the scan lines 11 extend in the lateral direction. The cathode lines 124 extend in the lateral direction, however, it is a convenient expression in the equivalent circuit; in an actual device, the cathode 124 is formed to cover all the display area 10 as explained in FIG. 2. The video signal liens 12 and the power lines 13 extend in the longitudinal direction. The pixel 14 is formed in the area surrounded by the scan lines 11 and the video signal lines 12 or the power lines 13.

In FIG. 3, the drain of the switching transistor T1 connects to the video signal line 12, and the gate connects to the scan line 11. The drain of the driving transistor T2 connects to the power line 13, and the source connects to the organic EL layer EL. The gate of the driving transistor T2 connects to the source of the switching transistor T1. The storage capacitance Cs is connected between the gate and the source of the driving transistor T2.

In FIG. 3, when the scan signal is applied to the switching transistor T1, the video signal is stored in the storage capacitance Cs through the switching transistor T1; the driving transistor T2 supplies current to the organic EL layer EL according to the stored charges in the storage capacitance Cs. The transistor explained in FIG. 2 is the driving transistor T2 in FIG. 3. The gate electrode 109 of the driving transistor T2 constitutes one electrode 1091 of the storage capacitance Cs, therefore, the one electrode 1091 has a large area; consequently, the gate electrode 109 of the driving transistor T2 is significantly influenced by charge up in the polyimide, which constitutes the TFT substrate 100.

FIG. 4 is a cross sectional view of the driving transistor T2 and its vicinity. In FIG. 4, the polyimide substrate 100 is formed on the glass substrate 90; the undercoat film 101 is formed on the polyimide substrate 100. The semiconductor film 107 is formed on the undercoat film 101. The semiconductor film 107 is made of e.g. the oxide semiconductor. The gate insulating film 108 is formed on the semiconductor film 107; the gate electrode 109 is formed on the gate insulating film 108. In the semiconductor film 107, the channel is formed beneath the gate electrode 109, and the other portions are the drain or the source. The gate electrode 109 of the driving transistor extends to other area and constitutes one electrode 1091 of the storage capacitance Cs.

Forming images continuously in the organic EL display device means DC voltage is continuously applied to the gate electrode 109. Applying voltage to the gate electrode 109 means the same voltage is applied to the one electrode that constitutes the storage capacitance Cs. It is noted that the area of the one electrode for the storage capacitance Cs is bigger than the area of the gate electrode 109.

Consequently, as depicted in FIG. 4, a part of the polyimide, which constitutes the TFT substrate 100, charges up. The charges that charge up the polyimide have moved from another place of the polyimide substrate 100, e.g. from the polyimide under the TFT. FIG. 4 shows that minus charges have moved to the place corresponding to the one electrode of the storage capacitance Cs through the resistance Rp; as a result, the polyimide substrate 100 under the TFT charges up to plus potential. Consequently, the source current changes influenced by this charge up. Such a fluctuation in characteristics in the TFT influenced by the charge up in the substrate 100 is conspicuous in the TFT using the oxide semiconductor 107.

The TFT using the oxide semiconductor 107 has a characteristic of low leak current. This means the voltage of the pixel electrode can be held stably for a long period. Therefore, low frequency operation is possible, thus low power consumption can be realized by using the oxide semiconductor 107 for the TFT. The mobility of the carriers in the oxide semiconductor 107, however, is sometimes not enough to form the peripheral driving circuit.

On the other hand, the mobility of the carriers in the LTPS is high. The LTPS, however, has a higher leak current compared with the oxide semiconductor. Therefore, it is reasonable to use the TFTs of the oxide semiconductors for the driving TFT or the switching TFT in the pixels in the display area, and to use the TFTs of the LTPS in the peripheral driving circuit. Such a structure is called as a hybrid structure.

FIG. 5 is a cross sectional view that the TFT of the oxide semiconductor film 107 and the TFT of the LTPS film 102 are formed on the same substrate 100. The TFT of the oxide semiconductor film 107 is formed in the display area, and the TFT of the LTPS film 102 is formed in the peripheral driving circuit, therefore they are actually formed apart; in FIG. 5, however, the TFT of the oxide semiconductor film 107 and the TFT of the LTPS film 102 are set side by side to easily compare the layer structures between them.

In FIG. 5, left side is the TFT of the LTPS film 102, and right side is the TFT of the oxide semiconductor film 107. In FIG. 5, the TFT substrate 100 made of polyimide is formed on the glass substrate 90; the undercoat film 101 is formed on the TFT substrate 100. The structure of the undercoat film 101 is the same as explained in FIG. 2. The semiconductor film 102 made of the LTPS is formed on the undercoat film 101. The LTPS film 102 is formed as that: at the outset, the a-Si film is formed by CVD on the undercoat film 101, then the a-Si film is converted to the polysilicon film by irradiating the excimer laser to the a-Si film. The LTPS film 102 is formed in a thickness of approximately 50 nm.

The first gate insulating film 103 is formed covering the LTPS film 102; the first gate electrode 104 is formed on the first gate insulating film 103. The first gate electrode 104 is made of metal or alloy of e.g. Mo, MoW, or a laminated film of e.g. Ti film—Al film—Ti film. In FIG. 5, the channel is formed in the LTPS film 102 at the region corresponding to the first gate electrode 104, the drain 1021 and the source 1022 are formed at the both sides of the channel.

The first interlayer insulating film 105 made of silicon nitride (SiN) and the second interlayer insulating film 106 made of silicon oxide (SiO) are formed covering the first gate electrode 104. The first interlayer insulating film 105 is preferably made of SiN for the stability of the characteristics of the TFT of the LTPS film 102. On the other hand, if the oxide semiconductor film 107, which is formed on the right hand side of FIG. 5, contacts to the SiN film, the characteristics of the oxide semiconductor film 107 change by hydrogen supplied from the SiN film. The second interlayer insulating film 106 is formed by the SiO film to avoid this problem.

In the right hand side of FIG. 5, the oxide semiconductor film 107 is formed by e.g. IGZO on the second interlayer insulating film 106. A thickness of the oxide semiconductor film 107 is e.g. 10 to 100 nm. The second gate insulating film 108 is formed covering the oxide semiconductor film 107. The second gate electrode 109 is formed on the second gate insulating film 108 and above the oxide semiconductor film 107. In the oxide semiconductor film 107, the channel is formed at the place corresponding to the second gate electrode 109; the drain 1071 and the source 1072 are formed at the both sides of the channel.

The third interlayer insulating film 110 is formed by SiO covering the second gate electrode 109. Since the third interlayer insulating film 110 is formed in vicinity of the oxide semiconductor film 107 via the second gate insulating film 108, it is formed by SiO so that it can supply oxygen to the oxide semiconductor film 107 to stabilize the characteristics of the oxide semiconductor film 107.

In the left hand side TFT in FIG. 5, the through holes 115 and 116 are formed through five films, namely, the third interlayer insulating film 110, the second gate insulating film 108, the second interlayer insulating film 106, the first interlayer insulating film 105, and the first gate insulating film 103 to connect the drain electrode 111 with the drain 1021 and to connect the source electrode 112 to the source 1022. In the right hand side TFT, the through holes 117 and 118 are formed in the third interlayer insulating film 110 and the second gate insulating film 108 to connect the drain electrode 113 to the drain 1071 and to connect the source electrode 114 to the source 1072.

In FIG. 5, the through holes 115 and 116 for the LIPS film 102 and the through holes 117 and 118 for the oxide semiconductor film 107 are formed simultaneously. The hydrofluoric acid (HF) is used for cleansing when the through holes 115 and 116 for the LIPS film 102 are made. An etching stopper made of e.g. metal may be formed on the oxide semiconductor film 107 at the place where the through holes 117 and 118 are formed to prevent the oxide semiconductor film 107 from being washed away by the hydrofluoric acid (HF) at the through holes 117 and 118.

In FIG. 5, during the display device operates, the charges are induced in the TFT substrate 100 at the place corresponding to the TFT made of the oxide semiconductor film 107 as explained in FIGS. 3 and 4. The characteristics of the TFT of the oxide semiconductor film 107 change due to the charges in the polyimide substrate 100. By the way, only the undercoat film 101 exists under the oxide semiconductor film 107 in FIG. 4, while a laminated film of four layers of the second interlayer insulating film 106, the first interlayer insulating film 105, the first gate insulating film 103 and the undercoat film 101 exists under the oxide semiconductor film 107 in FIG. 5; however, the phenomenon of the charge up in the TFT substrate 100 is the same.

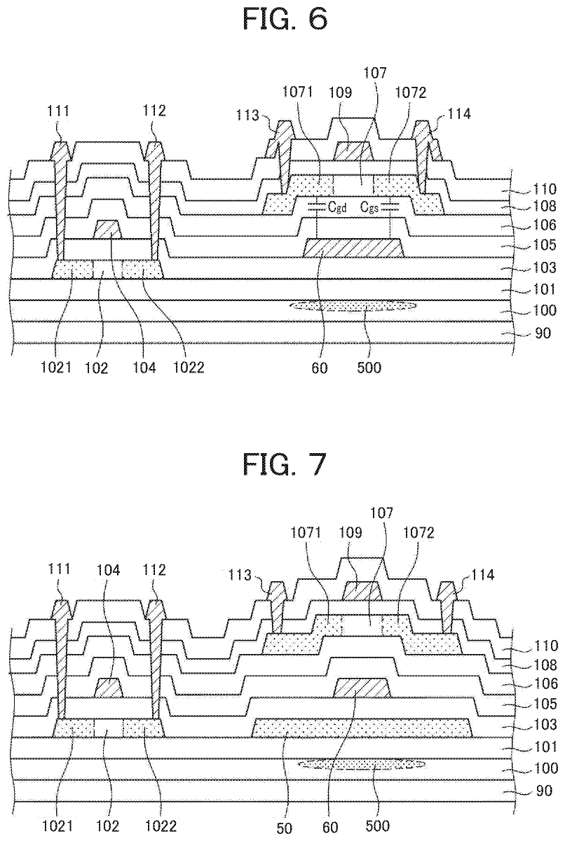

FIG. 6 is a cross sectional view of the TFT as a comparative example to countermeasure this problem. In FIG. 6, the TFT of the LTPS film 102 in the left hand side is the same as explained in FIG. 5. In the right hand side TFT in FIG. 6, the shield film 60 is formed under the oxide semiconductor film 107 via the second interlayer insulating film 106 and the first interlayer insulating film 105. The shield film 60 is applied with e.g. the ground potential (GND), the charges induced in the TFT substrate 100 is shielded by the shield film 60. By the way, the shield film 60 can be a bottom gate electrode (a third gate electrode) of the TFT of the oxide semiconductor film 107 by supplying the gate voltage. The shaded area 500 in FIG. 6 means charges induced in the TFT substrate 100.

The shield film 60 is formed by the same material as the first gate electrode 104 and formed simultaneously with the first gate electrode 104. The shield film 60, which is made of metal, can work as the light shading film for the oxide semiconductor film 107 against the light from the rear side. On the other hand, if enough shield effect is necessary, the shield film 60 must have a certain area.

However, if the area of the shield film 60 is made bigger, the floating capacitance Cgd between the shield film 60 and the drain 1071 of the oxide semiconductor film 107, and the floating capacitance Cgs between the shield film 60 and the source 1072 of the oxide semiconductor film 107 increase. The floating capacitances Cgd and Cgs cause a so called jumping voltage of the gate voltage to the pixel electrode or the anode when the shield film 60 is used as the bottom gate; in addition, the floating capacitances Cgd and Cgs cause a delay of operating speed of the TFT when the shield film 60 is applied with the ground voltage (GND).

FIG. 7 is a cross sectional view that countermeasures the above problems according to embodiment 1 of the present invention. In FIG. 7, the structure of the TFT of the LTPS film 102 is the same as explained in FIGS. 5 and 6. The TFT of the oxide semiconductor film 107 in the right hand side of FIG. 7 differs from the structure of FIG. 6.

In FIG. 7, the third bottom gate electrode 60 (the shield film 60) formed under the oxide semiconductor film 107 has least area as far as to satisfy the roles of the bottom gate and of the light shading film. Therefore, it does not have a enough shield effect against the charges induced in the TFT substrate 100. However, since the area of the third gate electrode 60 is made small, the floating capacitances Cgd between the drain 1071 and the third gate electrode 60 and Cgs between the source 1072 and the third gate electrode 60 are made as small as possible.

In FIG. 7, the shield film 50 formed by the LTPS film shields the charges induced in the TFT substrate 100. The shield film 50 is formed simultaneously when the LTPS film 102 for the TFT on the left hand side is made. The shield film 50 is formed by the LTPS, however, the conductivity is given by the ion implantation.

For example, the ground voltage (GND) is applied to the shield film 50. In the meantime, the ground voltage is a reference voltage, which is not necessarily the earth voltage. Namely, the reference voltage can be a cathode voltage.

As depicted in FIG. 7, there is the first gate insulating film 103 in addition to the first interlayer insulating film 105 and the second interlayer insulating film 106 between the shield film 50 made of the LIPS film and the drain 1071 or the source 1072 of the oxide semiconductor film 108; therefore, the floating capacitance can be made small. In other words, since the floating capacitance with the oxide semiconductor film 107 can be made small, the area of the shield film 50 can be made bigger to have thorough shield effect.

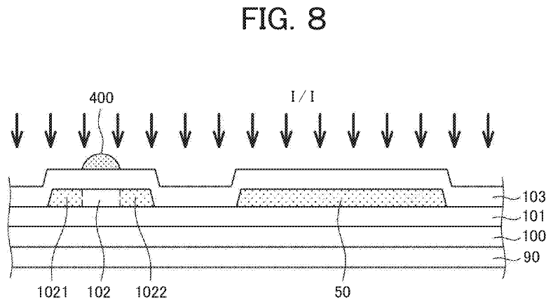

FIG. 8 is a cross sectional view of the interim structure in the process to form the shield film 50. The shield film 50 of the LIPS film is patterned simultaneously when the LIPS film 102 for the LIPS TFT is formed. After that, the first gate insulating film 103 is formed covering the LIPS film 102 for the TFT and the LIPS film 50 for the shield film 50. Subsequently, the resist 400 is formed on the gate insulating film 103 at the place corresponding to the region where the channel is formed in the LIPS film 102.

After that, Phosphorus (P), or Boron (B) or etc. is doped by the ion implantation to give conductivity to the LIPS film 102 other than the region where the resist 400 covers. FIG. 8 is a cross sectional view that the drain 1021 and the source 1022 are formed in the LIPS film 102 by the ion implantation. As depicted in FIG. 8, the LIPS film 50 that constitutes the shield film 50 is simultaneously given conductivity when the drain 1021 and the source 1021 are formed.

In the ion implantation in FIG. 8, Phosphorus (P) is e.g. doped in 1×10¹⁴ ions/cm². As depicted in FIG. 8, additional process is not necessary to form the shield film 50 in the present invention.

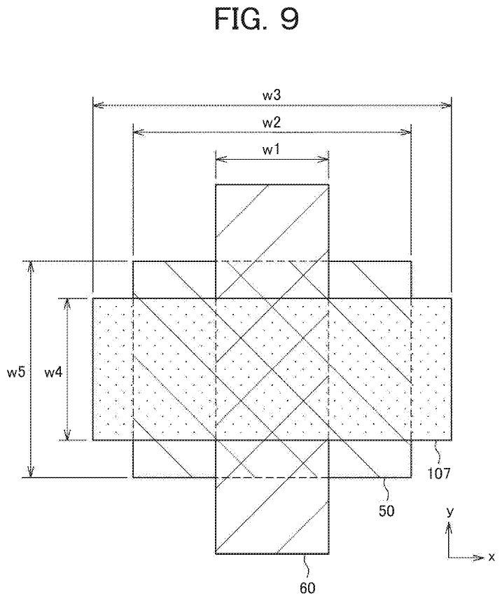

FIG. 9 is a plan view of the TFT of the oxide semiconductor film 107. In FIG. 9, the shield film 50 made of the LIPS is formed as the lower most layer. The third gate electrode 60, which constitutes the bottom gate, is formed over the shield film 50; the oxide semiconductor film 107 is formed over the third gate electrode 60. In FIG. 9, the lateral direction (x direction) is the channel length direction and the longitudinal direction (y direction) is the channel width direction.

As shown in FIG. 9, the lateral width w2 of the shield film 50 is bigger than the lateral width w1 of the third gate electrode 60. In FIG. 9, the width w3 in the lateral direction of the oxide semiconductor film 107 is bigger than the width w2 in the lateral direction of the shield film 50; however, as far as the shield effect is considered, it is preferable that the width w2 in the lateral direction of the shield film 50 is bigger than the width w3 in the lateral direction of the oxide semiconductor film 107. The longitudinal width w5 of the shield film 50 is bigger than the longitudinal width w4 of the oxide semiconductor film 107. It is noted that the distance between the shield film 50 made of the LTPS and the oxide semiconductor film 107 is bigger than the distance between the third gate electrode 60 and the oxide semiconductor film 107; thus, the area of the shield film 50, made of the LTPS film, can be made bigger.

In the meantime, in FIG. 6, if the bottom gate 60 is not necessary and if the bottom gate 60 as the light shading film is not necessary, the third electrode 60 in FIG. 7 can be eliminated.

As described above, according to the present invention, the influence to the semiconductor film 107 by the charges induced in the TFT substrate 100 can be shielded by the shield film 50 made of the LTPS film; at the same time, the increase of the floating capacitance because of the shield film 50 can be suppressed.

### Embodiment 2

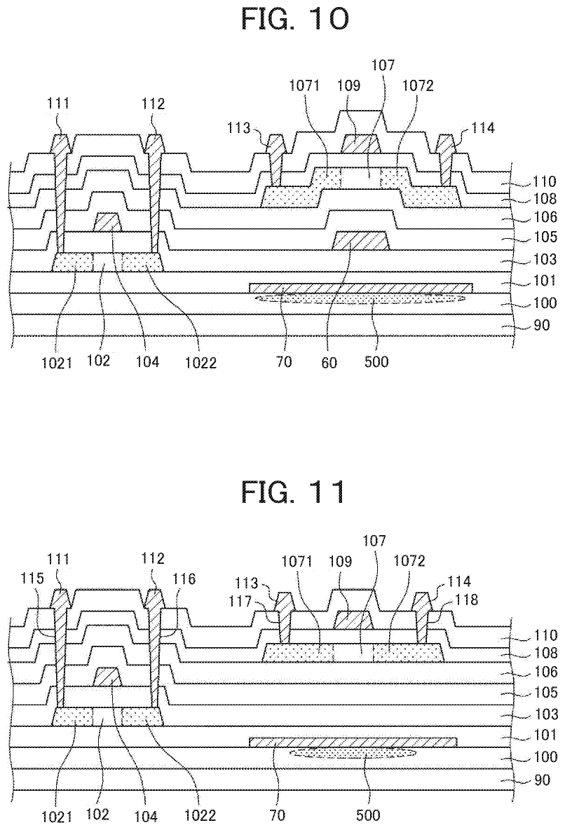

FIG. 10 is a cross sectional view according to embodiment 2 of the present invention. In embodiment 1, the LIPS film 50 is used for the shield against the charges induced in the TFT substrate 100. In the structure of embodiment 1, there are three insulating films of the second interlayer insulating film 106, the first interlayer insulating film 105 and the first gate insulating film 103 between the oxide semiconductor film 107 and the shield film 50, therefore, increase of the floating capacitance can be suppressed.

The structure of embodiment 2 shown in FIG. 10 has a shield film 70 formed under the undercoat film 101, thus, the capacitance between the shield film 70 and the oxide semiconductor film 107 can be further decreased. In FIG. 7, the shield film 70 is formed by the conductive material under the undercoat 101. The conductive material is preferably metal, the metal can be the same material as the gate electrode.

In FIG. 10, there are the second interlayer insulating film 106, the first interlayer insulating film 105, the first gate insulating film 103 and the undercoat film 101 between the oxide semiconductor film 107 and the shield film 70; therefore, the distance between the oxide semiconductor film 107 and the shield film 70 can be bigger than that of embodiment 1. In addition, the undercoat film 101 has, in many cases, a three-layer structure of the SiO film, SiN film, and the SiO film; therefore, the distance can be made effectively larger.

If the shield film 70 is formed by metal, it can work as a light shading film. A thickness of the shield film 70 is e.g. 50 nm, which can have enough effect for the electrical shield. On the other hand, if light shading effect is necessary, a thickness is preferably as thick as 100 nm.

The oxide semiconductor film 107 has a channel length and the channel width; in the channel length direction, the length of the shield film 70 is preferably bigger than the length of the channel; in the channel width direction, the width of the shield film 70 is preferably bigger than the width of the channel.

FIG. 11 is a cross sectional view of a second example of embodiment 2. The shield film 70 in this example is formed by metal and has a light shading effect. Therefore, if the TFT of the oxide semiconductor film 107 does not need the bottom gate, the third gate electrode 60, which has a light shading effect, can be eliminated.

In FIG. 11, only the shield film 70 exists under the oxide semiconductor film 107 via the insulating films. Therefore, the floating capacitance can be further decreased than that of the structure of FIG. 10. The structure of the shield film 70 is the same as explained in FIG. 10.

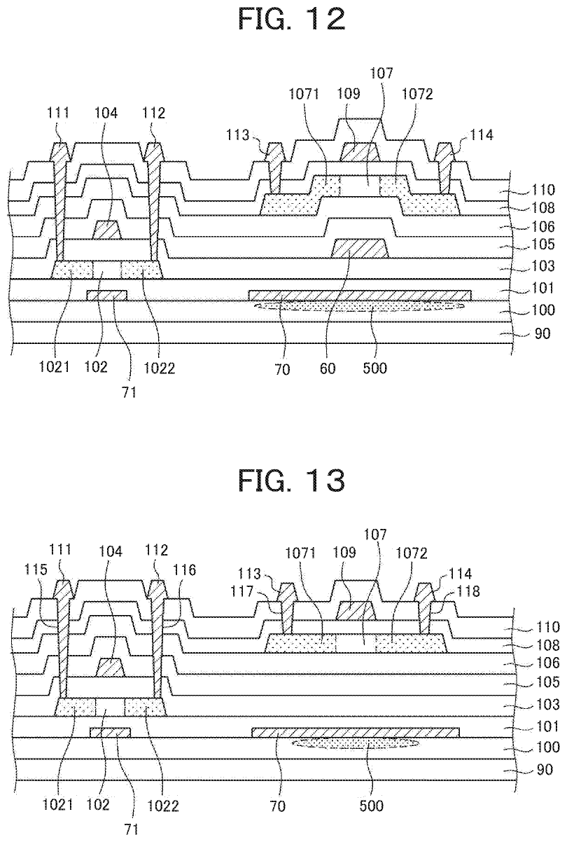

FIG. 12 is a cross sectional view of a third example of embodiment 2. FIG. 12 differs from FIG. 10 in that the structure of FIG. 12 has a light shading film 71 under the LTPS film 102. The LTPS film 102, too, is influenced by charge up in the TFT substrate 100. In addition, a photo current is produced by the light from the rear side in the LTPS film 102, too. FIG. 12 has a shield film 71 for the LTPS film 102 to make shield effect against the charge up in the TFT substrate 100 and to make the light shading effect.

In FIG. 12, the width of the shield 71 is formed in an area that just to cover the channel of the LTPS film 102 from the rear side for electrical shielding of the channel region and for light shading of the channel region. On the other hand, in a plan view, overlapping between the drain 1021 and the shield 71 and between the source 1022 and the shield 71 are made small to prevent generation of the floating capacitance.

FIG. 13 is a cross sectional view of a fourth example of embodiment 2. FIG. 13 differs from FIG. 11 in that FIG. 13 has a shield film 71 under the LIPS film 102. Other structures of FIG. 13 is the same as that of FIG. 11. The structure of the shield film 71 of FIG. 13 is the same as explained in FIG. 12. The influence of the charge up in the TFT substrate 100 can be mitigated in the LIPS film 102 as well as in the oxide semiconductor film 107 according to the structure of FIG. 13.

### Embodiment 3

Embodiment 1 and embodiment 2 explain when the present invention is applied to the organic EL display device. The present invention can be applied to the liquid crystal display device. Namely, flexible display device, using the polyimide substrate, is also required in the liquid crystal display device.

In the liquid crystal display device, however, unlike the organic EL display device, the driving transistor does not exist in the pixel area, but only the switching transistor exists in the pixel area. However, the switching transistor also is influenced by charge up in the polyimide substrate. Namely, the threshold voltage of the switching transistor is influenced by the charge up of the polyimide substrate, consequently, the charges in the pixel capacitance according to the video signal get influenced.

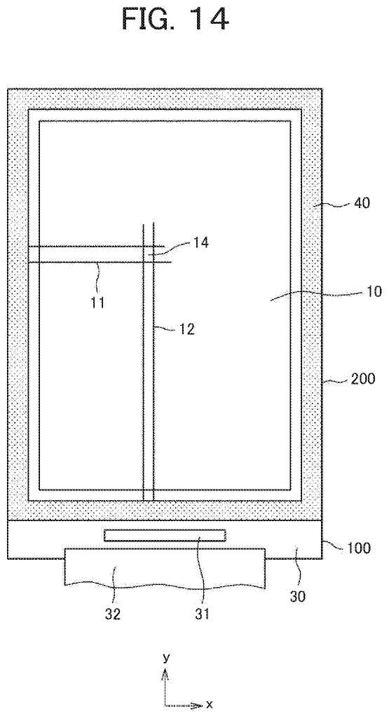

FIG. 14 is a plan view of the liquid crystal display device. In FIG. 14, the TFT substrate 100 adheres to the counter substrate 200 through the sealant 40 and the liquid crystal is sealed inside. The display area 10 is formed in the area where the TFT substrate 100 and the counter substrate 200 overlap. In the display area 10, the scan lines 11 extend in the lateral direction (x direction) and are arranged in the longitudinal direction (y direction); the video signal lines 12 extend in the longitudinal direction and are arranged in the lateral direction. The pixel 14 is formed in the area surrounded by the scan lines 11 and the video signal lines 12.

The terminal area 30 is formed on the TFT substrate 100 where the counter substrate 200 and the TFT substrate 100 do not overlap. The driver IC 31 is installed in the terminal area 30 and the flexible wiring substrate 32 connects to the terminal area 30.

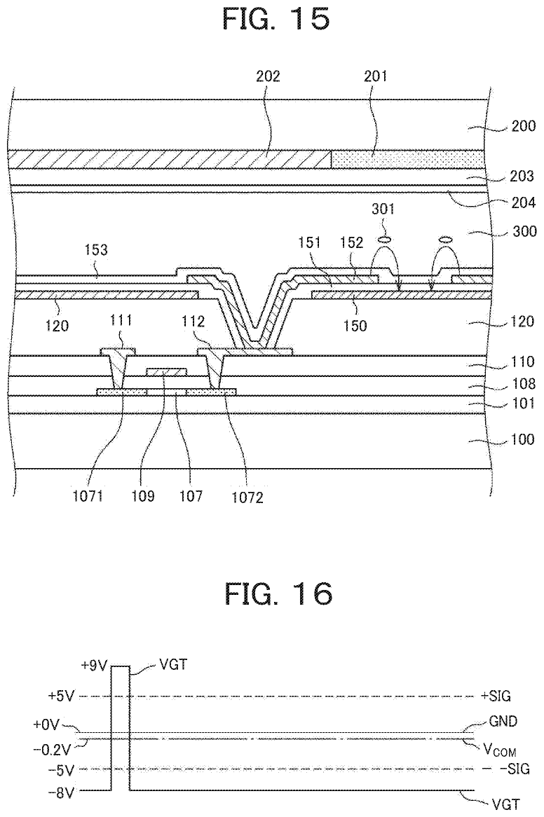

FIG. 15 is a cross sectional view of the pixel area of the liquid crystal display device according to the present invention. The TFT in FIG. 15 is a switching TFT, however, the cross sectional view is the same as the driving TFT in FIG. 2. Namely, the TFT is a top gate type and the oxide semiconductor film 107 is used for the TFT. In FIG. 15, the structures are the same as FIG. 2 up to the organic passivation film 120.

In FIG. 15, the common electrode 150 is formed by ITO in a plane shape on the organic passivation film 120; the capacitance insulating film 151 made of SiN is formed covering the common electrode 150. The pixel electrode 152 is formed by ITO on the capacitance insulating film 151. The pixel electrode 152 is comb like shaped in a plan view. The alignment film 153 is formed covering the pixel electrode 152 to give an initial alignment for the liquid crystal molecules 301.

When the video signal is applied to the pixel electrode 152, the lines of forces are generated as arrows in FIG. 15 between the pixel electrode 152 and the common electrode 150; consequently, the liquid crystal molecules are rotated, and a transmittance in the pixel is controlled. In addition, the holding capacitance is generated between the pixel electrode 152 and the common electrode 150 sandwiching the capacitance insulating film 151.

In FIG. 15, the counter substrate 200 is set opposing to the TFT substrate 100 sandwiching the liquid crystal layer 300. The black matrix 202 and the color filters 201 are formed on inside of the counter substrate 200; the overcoat film 203 is formed covering the black matrix 202 and the color filters 201; the alignment film 204 is formed on the overcoat film 203.

In FIG. 15, the TFT substrate 100 and the counter substrate 200 are formed by polyimide. In the manufacturing process, the TFT substrate 100 made of the polyimide is formed on the glass substrate; however, after the liquid crystal display device is completed, the glass substrate is removed from the TFT substrate 100 by e.g. laser abrasion. It is the same for the counter substrate 200 made of polyimide.

The same voltage as the scan line 11 is applied to the gate electrode 109 in FIG. 15. FIG. 16 is voltage that is applied to the scan line 11 in the case the TFT is a top gate type as shown FIG. 15. In FIG. 16, VGT is the gate voltage, GND is the ground voltage, Vcom is the common voltage. SIG means the level of the video signal, however, SIG is not applied to the gate electrode 109. As shown in FIG. 16, the gate electrode, namely, the scan line 11 is applied with +9V only when they are selected; however, most of the time, the voltage −8V is applied to them. Therefore, the charges are induced in the polyimide substrate as explained in embodiment 1.

These charges change the threshold voltage of the switching transistor. The change of threshold voltage means changes in reproducing of brightness. Therefore, if e.g. the structure of embodiment 1 is applied, the influence caused by charge up in the polyimide substrate 100 can be mitigated, thus, the change in brightness can be suppressed in the liquid crystal display device. Therefore, the present invention can be applied to the liquid crystal display device.

By the way, the influence by the scan line voltage to the charge up in the polyimide substrate is explained in the liquid crystal display device in this embodiment, however, the influence by the scan line voltage to the polyimide substrate is the same in the organic EL display device.

The liquid crystal display device also can adopt the hybrid structure, namely, combining the merit of the TFT of the oxide semiconductor and the merit of the TFT of the LTPS semiconductor. Namely, the TFT of the oxide semiconductor is used in the pixel area to realize the less leak current and thus, the less change of the voltage in the pixel electrode. On the other hand, the TFT of the LTPS semiconductor is used in the peripheral driving circuit to realize the high performance driving circuit. Such a liquid crystal display device also has a problem of charge up in the TFT substrate, especially if the polyimide substrate is used. Therefore, the present invention can be applied to those hybrid liquid crystal display device: namely, mitigating the influence of the charge up in the polyimide substrate to the TFT, and thus, realize the liquid crystal display device of stable characteristics.

What is claimed is:

1. A display device comprising:
a first TFT of an oxide semiconductor film and
a second TFT of a polysilicon film formed on the substrate made of resin, wherein
the first TFT and the second TFT do not overlap in a plan view,
a distance between the second TFT and the substrate is shorter than a distance between the first TFT and the substrate in a cross sectional view,
a second polysilicon film is formed between the oxide semiconductor film and the substrate, and
the second polysilicon film is made of the same material as the first polysilicon film and is formed on the same layer that the first polysilicon is formed.

2. The display device according to claim 1,
wherein, in a channel length direction of the oxide semiconductor film, a length of the second polysilicon film is longer than a length of the oxide semiconductor.

3. The display device according to claim 1,
wherein, in a channel width direction of the oxide semiconductor film, a width of the second polysilicon film is wider than a width of the oxide semiconductor film.

4. The display device according to claim 1,
Wherein, a metal film is formed under the oxide semiconductor film via an insulating film, the metal film is made of the same material as a gate electrode of the second TFT, and
wherein, in a channel length direction of the oxide semiconductor film, a length of the metal film is shorter than a length of the oxide semiconductor film.

5. The display device according to claim 1,
wherein a metal film is formed under the oxide semiconductor film via an insulating film, the metal film is made of the same material as a gate electrode of the second TFT, and
wherein, in a channel length direction of the oxide semiconductor film, a length of the metal film is shorter than a length of the second polysilicon film.

6. The display device according to claim 1,
wherein a metal film is formed under the oxide semiconductor film via an insulating film, the metal film is made of the same material as a gate electrode of the second TFT,
wherein a gate voltage is applied to the metal film.

7. The display device according to claim 1,
wherein a metal film is formed under the oxide semiconductor film via an insulating film, the metal film is made of the same material as a gate electrode of the second TFT, and
wherein a reference voltage is applied to the metal film.

8. The display device according to claim 1,
wherein a reference voltage is applied to the second polysilicon film.

9. The display device according to claim 1,
wherein the first TFT is a top gate type TFT.

10. The display device according to claim 1,
wherein the second TFT is a top gate type TFT.

11. A display device comprising:
a first TFT of an oxide semiconductor film formed on a substrate made of resin, wherein
a first conductive film is formed on the substrate overlapping with the oxide semiconductor film, in a plan view,
an undercoat film made of an inorganic film is formed on the first conductive film,
the oxide semiconductor film has a channel length and a channel width, and
wherein, in the channel length direction, a length of the first conductive film is longer than a length of the oxide semiconductor film.

12. The display device according to claim 11,
wherein, in the channel width direction, a width of the first conductive film is wider than a width of the oxide semiconductor film.

13. The display device according to claim 11,
wherein the first conductive film is made of metal.

14. The display device according to claim 1,
wherein a reference voltage is applied to the metal film.

15. The display device according to claim 11,
wherein a second TFT of a polysilicon film is formed on the substrate, the first TFT and the second TFT do not overlap in a plan view, and
a distance between the second TFT and the substrate is shorter than a distance between the first TFT and the substrate, in a cross sectional view.

16. The display device according to claim 15,
wherein a second conductive film, made of a same material as the first conductive film, is formed between the substrate and the undercoat film in overlapping the polysilicon film in a plan view.

17. The display device according to claim 15,
wherein the polysilicon film has a channel length and a channel width, and
wherein, in a channel length direction, a length of the polysilicon film is longer than a length of the second conductive film

18. The display device according to claim 16,
wherein a reference voltage is applied to the second conductive film.

19. The display device according to claim 15,
wherein a metal film, made of a same material as a gate electrode of the second TFT, is formed between the oxide semiconductor film and the undercoat film and on the same layer as the gate electrode of the second TFT is made, and
wherein, in a channel length direction, a length of the metal film is shorter than a length of the oxide semiconductor film.

20. The display device according to claim 19,
wherein a gate voltage is applied to the metal film.
